(19) United States
(12) Patent Application Publication
(10) Pub. No.: US 2025/0113537 A1
(43) Pub. Date: Apr. 3, 2025

(54) SEMICONDUCTOR STRUCTURE WITH PLACEHOLDER POSITION MARGIN

(71) Applicant: International Business Machines Corporation, Armonk, NY (US)

(72) Inventors: Ruilong Xie, Niskayuna, NY (US); Kisik Choi, Watervliet, NY (US); Tao Li, Slingerlands, NY (US); Joshua M. Rubin, Albany, NY (US)

(21) Appl. No.: 18/374,924

(22) Filed: Sep. 29, 2023

(51) Int. Cl. H01L 29/423; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 64/018; H10D 64/021; H10D 84/83

(57) ABSTRACT

A semiconductor structure having improved placeholder position margin is provided. In embodiments, the semiconductor structure includes a nanosheet transistor including a plurality of spaced apart and vertically stacked semiconductor channel material nanosheets, a gate structure wrapped around each of the semiconductor channel material nanosheets, a first source/drain region located on a first side of the gate structure and a second source/drain region located on a second side of the gate structure. The gate structure has a first gate thickness under a bottommost semiconductor channel material nanosheet of the plurality of semiconductor channel material nanosheets that is greater than a second gate thickness that is located between the bottommost semiconductor channel material nanosheet and a nearest overlying semiconductor channel material nanosheet of the plurality of semiconductor channel material nanosheets.

### BACKGROUND

The present application relates to semiconductor technology, and more particularly to a semiconductor structure having improved placeholder position margin.

In recent years, the semiconductor industry has been transitioning from finFETs to gate-all-around stacked nanosheet transistor architecture. Relative to finFETs, nanosheet transistors deliver more drive current by increasing the channel widths in the same circuit footprint. The gate-all-around design improves channel control and minimizes short-channel effects.

### SUMMARY

A semiconductor structure having improved placeholder position margin without containing a bottom dielectric isolation layer is provided.

In one embodiment of the present application, the semiconductor structure includes a nanosheet transistor including a plurality of spaced apart and vertically stacked semiconductor channel material nanosheets, a gate structure wrapped around the plurality of spaced apart and vertically stacked semiconductor channel material nanosheets, a first source/drain region located on a first side of the gate structure and a second source/drain region located on a second side of the gate structure, wherein the gate structure has a first gate thickness under a bottommost semiconductor channel material nanosheet of the plurality of spaced apart and vertically stacked semiconductor channel material nanosheets that is greater than a second gate thickness that is located between the bottommost semiconductor channel material nanosheet and a nearest overlying semiconductor channel material nanosheet of the plurality of spaced apart and vertically stacked semiconductor channel material nanosheets. The structure further includes a backside source/drain contact structure electrically contacting the second source/drain region of the nanosheet transistor.

In another embodiment of the present application, the semiconductor structure includes a nanosheet transistor including a plurality of spaced apart and vertically stacked semiconductor channel material nanosheets, a gate structure wrapped around the plurality of spaced apart and vertically stacked semiconductor channel material nanosheets, a first source/drain region located on a first side of the gate structure and a second source/drain region located on a second side of the gate structure, wherein the gate structure has a first gate thickness under a bottommost semiconductor channel material nanosheet of the plurality of spaced apart and vertically stacked semiconductor channel material nanosheets that is greater than a second gate thickness that is located between the bottommost semiconductor channel material nanosheet and a nearest overlying semiconductor channel material nanosheet of the plurality of spaced apart and vertically stacked semiconductor channel material nanosheets. The structure of this embodiment further includes a bottom inner spacer structure located laterally adjacent to the first gate thickness of the gate structure, an upper inner spacer located above the bottom inner spacer structure and positioned laterally adjacent to the second gate thickness of the gate structure, a backside source/drain contact structure electrically contacting the second source/drain region of the nanosheet transistor, and a backside source/drain contact placeholder structure located beneath the first source/drain region, wherein a semiconductor buffer layer is located between the first source/drain region and the backside source/drain contact placeholder structure.

In a further embodiment of the present application, the semiconductor structure includes a nanosheet transistor including a plurality of spaced apart and vertically stacked semiconductor channel material nanosheets, a gate structure wrapped around the plurality of spaced apart and vertically stacked semiconductor channel material nanosheets, a first source/drain region located on a first side of the gate structure and a second source/drain region located on a second side of the gate structure, wherein the gate structure has a first gate thickness under a bottommost semiconductor channel material nanosheet of the plurality of spaced apart and vertically stacked semiconductor channel material nanosheets that is greater than a second gate thickness that is located between the bottommost semiconductor channel material nanosheet and a nearest overlying semiconductor channel material nanosheet of the plurality of spaced apart and vertically stacked semiconductor channel material nanosheets. In this embodiment, the structure further includes a bottom inner spacer structure having a first vertical height and located laterally adjacent to the first gate thickness of the gate structure, the bottom inner spacer structure including a first inner spacer and a second inner spacer that are vertically spaced apart by a semiconductor material liner, and an upper inner spacer having a second vertical height and located above the bottom inner spacer structure and positioned laterally adjacent to the second gate thickness of the gate structure, wherein the first vertical height is greater than the second vertical height.

### BRIEF DESCRIPTION OF THE DRAWINGS

FIG. 1 is a top-down view of an exemplary semiconductor device layout that can be employed in accordance with an embodiment of the present application, the semiconductor device layout includes a plurality of active areas oriented along a first direction, and a plurality of functional gate structures that are oriented in a second direction which is perpendicular to the first direction; in the drawing cut A-A, and cut B-B are shown.

FIGS. 2A and 2B are cross sectional views of an exemplary semiconductor structure corresponding to cuts A-A and B-B shown in FIG. 1, respectively, that can be employed in the present application, the semiconductor structure includes a first semiconductor layer, an etch stop layer, a second semiconductor layer, and a material stack of alternating sacrificial semiconductor material layers and semiconductor channel material layers, wherein the bottommost semiconductor channel material layer has a thickness that is less than a thickness of the other semiconductor channel material layers of the material stack.

FIGS. 3A and 3B are cross sectional views of the exemplary semiconductor structure shown in FIGS. 2A and 2B, respectively, after patterning the material stack, and forming a shallow trench isolation structure.

FIGS. 4A and 4B are cross sectional views of the exemplary semiconductor structure shown in FIGS. 3A and 3B, respectively, after forming a sacrificial gate structure, a hard mask cap and a gate spacer.

FIGS. 5A and 5B are cross sectional views of the exemplary semiconductor structure shown in FIGS. 4A and 4B, respectively, after nanosheet patterning of the previously patterned material stack, wherein the nanosheet patterning of the previously patterned material stack forms at least one nanosheet stack of alternating sacrificial semiconductor material nanosheets and semiconductor channel material nanosheets, and recessing, i.e., indenting, each sacrificial semiconductor material nanosheet of the at least one nanosheet stack.

FIGS. 6A and 6B are cross sectional views of the exemplary semiconductor structure shown in FIGS. 5A and 5B, respectively, after forming a conformal inner dielectric spacer layer.

FIGS. 7A and 7B are cross sectional views of the exemplary semiconductor structure shown in FIGS. 6A and 6B, respectively, after performing an isotropic etch back process on the conformal inner dielectric spacer layer to form inner spacers.

FIGS. 8A and 8B are cross sectional views of the exemplary semiconductor structure shown in FIGS. 7A and 7B, respectively, after forming a protective layer.

FIGS. 9A and 9B are cross sectional views of the exemplary semiconductor structure shown in FIGS. 8A and 8B, respectively, after removing the protective layer from all horizontal surfaces of the structure to provide a protective liner, and forming a placeholder cavity in the second semiconductor layer.

FIGS. 10A and 10B are cross sectional views of the exemplary semiconductor structure shown in FIGS. 9A and 9B, respectively, after forming a backside source/drain contact placeholder structure in the placeholder cavity and a semiconductor buffer layer on the source/drain contact placeholder structure.

FIGS. 11A and 11B are cross sectional views of the exemplary semiconductor structure shown in FIGS. 10A and 10B, respectively, after removing an upper portion of the protective liner and forming source/drain regions on the semiconductor buffer layer, and forming a first frontside interlayer dielectric (ILD) layer on the source/drain regions.

FIGS. 12A and 12B are cross sectional views of the exemplary semiconductor structure shown in FIGS. 11A and 11B, respectively, after removing the sacrificial gate structure to reveal an underlying nanosheet stack, and removing each sacrificial semiconductor material nanosheet of the revealed nanosheet stack.

FIGS. 13A and 13B are cross sectional views of the exemplary semiconductor structure shown in FIGS. 12A and 12B, respectively, after performing a nanosheet trimming process, wherein the nanosheet trimming process removes a reveled portion of the bottommost semiconductor channel material nanosheet of the nanosheet stack.

FIGS. 14A and 14B are cross sectional views of the exemplary semiconductor structure shown in FIGS. 13A and 13B, respectively, after forming a second frontside ILD layer, wherein the first frontside ILD layer and the second frontside ILD layer collectively form a middle-of-the-line (MOL) dielectric multilayered structure, forming frontside contact structures in the MOL dielectric multilayered structure, forming a frontside back-end-of-the-line (BEOL) structure and a carrier wafer.

FIGS. 15A and 15B are cross sectional views of the exemplary semiconductor structure shown in FIGS. 14A and 14B, respectively, after removing the first semiconductor layer to reveal the etch stop layer.

FIGS. 16A and 16B are cross sectional views of the exemplary semiconductor structure shown in FIGS. 15A and 15B, respectively, after removing the etch stop layer and the second semiconductor layer.

FIGS. 17A and 17B are cross sectional views of the exemplary semiconductor structure shown in FIGS. 16A and 16B, respectively, after forming a backside ILD layer.

FIGS. 18A and 18B are cross sectional views of the exemplary semiconductor structure shown in FIGS. 17A and 17B, respectively, after backside contact patterning that reveals at least one of the backside source/drain contact placeholder structures.

FIGS. 19A and 19B are cross sectional views of the exemplary semiconductor structure shown in FIGS. 18A and 18B, respectively, after removing the at least one revealed backside source/drain contact placeholder structure and the semiconductor buffer layer to physically expose one of the source/drain regions.

FIGS. 20A and 20B are cross sectional views of the exemplary semiconductor structure shown in FIGS. 19A and 19B, respectively, after forming a backside source/drain contact structure, and forming a backside interconnect structure.

FIGS. 21A-21B are cross sectional views of the exemplary semiconductor structure shown in FIGS. 3A and 3B, respectively, after nanosheet patterning of the previously patterned material stack, wherein the nanosheet patterning of the previously patterned material stack forms at least one nanosheet stack of alternating sacrificial semiconductor material nanosheets and semiconductor channel material nanosheets and forms an opening in the second semiconductor layer, and recessing each sacrificial semiconductor material nanosheet of the at least one nanosheet stack

FIGS. 22A-22B are cross sectional views of the exemplary semiconductor structure shown in FIGS. 21A and 21B, respectively, after performing further frontside and backside processing as illustrated in FIGS. 6A and 6B to 20A and 20B.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In the present application, a semiconductor structure is described and illustrated as containing at least one nanosheet transistor. A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the plurality of spaced apart semiconductor channel material nanosheets. In some cases, nanosheets transistors are thus referred to as gate-all-around (GAA) transistors. Nanosheet transistors provide considerable scaling with high drive current capability. Nanosheet transistors provide a larger drive current for a given footprint compared to finFET technology.

In the present application, the semiconductor structure includes a frontside and a backside. The frontside of the semiconductor structure of the present application includes a side of the structure that includes the at least one nanosheet transistor, frontside contact structures, and a frontside BEOL structure. The backside of the semiconductor structure of the present application is the side of the structure that is opposite the frontside. The backside includes a backside contact structure, and a backside interconnect structure.

In conventional nanosheet transistor processes in which a bottom dielectric isolation layer is present beneath the nanosheet transistor, there exists a challenge in controlling the levels of the backside source/drain contact placeholder structure and the source/drain region that is formed above the backside source/drain contact placeholder structure; in such processes a semiconductor buffer layer is typically formed between the backside source/drain contact placeholder structure and the source/drain region. If the backside source/drain contact placeholder structure level is too low such that the semiconductor buffer layer is exposed, there is a high risk of damaging the source/drain region during backside source/drain contact placeholder structure removal. If the backside source/drain contact placeholder structure level is too high such that the semiconductor buffer layer contacts one of the semiconductor channel materials nanosheets, it may cause a locally high on-resistance.

In other conventional nanosheet transistor processes in which no bottom dielectric isolation layer is used, the process window is even smaller than instances in which the bottom dielectric isolation layer is used. That is, there is a greater risk of damaging the source/drain region and a greater likelihood of having a high on-resistance when no bottom dielectric isolation layer is employed.

The present application overcomes the processing challenges mentioned above with existing nanosheet transistor devices that lack a bottom dielectric isolation layer. In the present application, the risk of damaging the source/drain region during backside source/drain contact placeholder structure removal and having a high on-resistance is mitigated. The present application thus provides a semiconductor structure having improved placeholder position margin. These and other aspect of the present application will now be described in greater detail herein below.

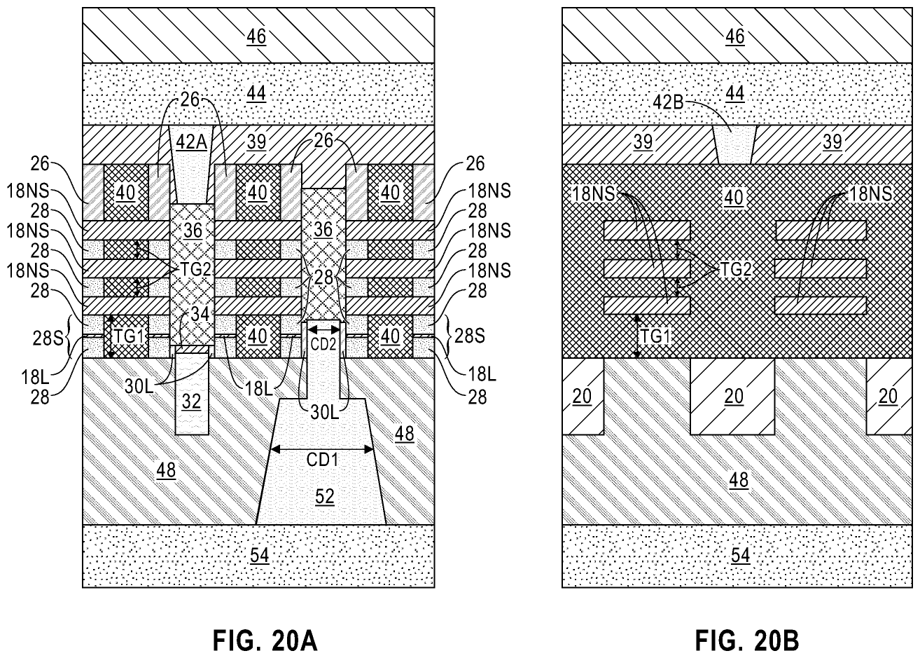

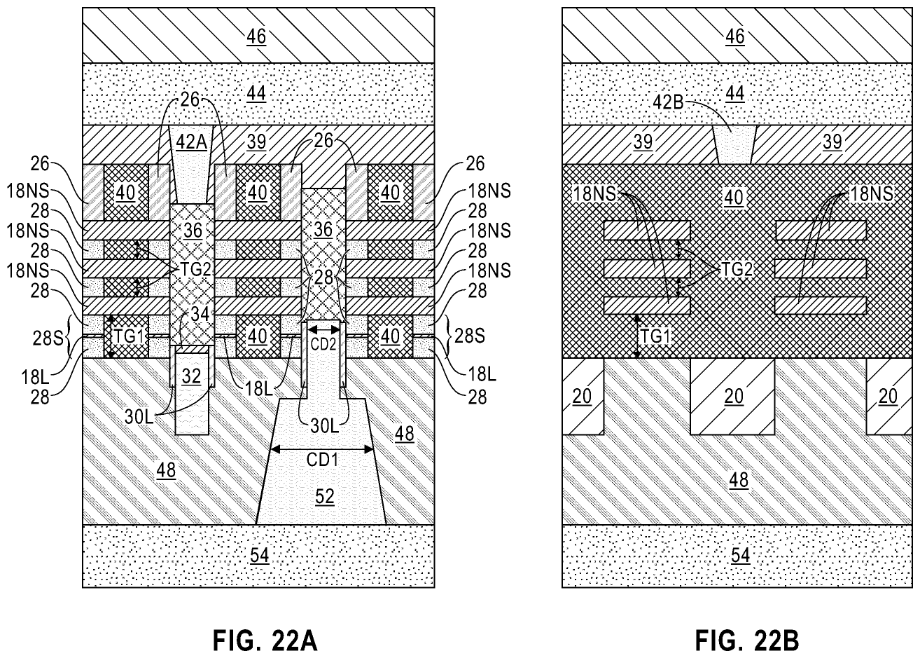

In one embodiment of the present application (see, for example, FIGS. 20A-20B or FIGS. 22A-22B), the semiconductor structure includes a nanosheet transistor including a plurality of spaced apart and vertically stacked semiconductor channel material nanosheets (i.e., stack of semiconductor channel material nanosheets 18NS illustrated in FIGS. 20A-20B and 22A-22B), a gate structure 40 wrapped around the plurality of spaced apart and vertically stacked semiconductor channel material nanosheets, a first source/drain region (e.g., source/drain region 36 found in the left hand-side of FIGS. 20A and 22A) located on a first side of the gate structure 40 and a second source/drain region (e.g., source/drain region 36 found in the right hand-side of FIGS. 20A and 22A) located on a second side of the gate structure 40, wherein the gate structure 40 has a first gate thickness TG1 under a bottommost semiconductor channel material nanosheet of the plurality of spaced apart and vertically stacked semiconductor channel material nanosheets that is greater than a second gate thickness TG2 that is located between the bottommost semiconductor channel material nanosheet and a nearest overlying semiconductor channel material nanosheet of the plurality of spaced apart and vertically stacked semiconductor channel material nanosheets. The structure further includes a backside source/drain contact structure 52 electrically contacting the second source/drain region of the nanosheet transistor. Forming TG1 with a thickness that is greater than TG2 allows wider process window during backside source/drain contact placeholder structure 32 formation, which will be explained in detail hereinbelow.

In embodiments of the present application (see, for example, FIGS. 20A-20B or FIGS. 22A-22B), the structure can further include a bottom inner spacer structure 28S located laterally adjacent to the first gate thickness TG1 of the gate structure 40, and an upper inner spacer located above the bottom inner spacer structure 28S and positioned laterally adjacent to the second gate thickness TG2 of the gate structure 40. The upper inner spacer can include inner spacer 28 located directly above the bottom inner spacer structure 28S.

In such embodiments (see, for example, FIGS. 20A-20B or FIGS. 22A-22B), the bottom inner spacer structure 28S includes a first inner spacer and a second inner spacer, wherein the first inner spacer is vertically spaced apart from the second inner spacer by a semiconductor material liner 18L.

In embodiments of the present application (see, for example, FIGS. 20A-20B or FIGS. 22A-22B), each semiconductor channel material nanosheet 18NS of the plurality of spaced apart and vertically stacked semiconductor channel material nanosheets and the semiconductor material liner 18L are composed of a compositionally same semiconductor material.

In embodiments of the present application, the bottom inner spacer structure 28S has a first vertical height, and the upper inner spacer (i.e., inner spacer 28 located directly above the bottom inner spacer structure 28S) has a second vertical height, wherein the first vertical height is greater than the second vertical height.

In embodiments of the present application (see, for example, FIGS. 20A-20B or FIGS. 22A-22B), the first source/drain region of the nanosheet transistor is located on a backside source/drain contact placeholder structure 32.

In embodiments of the present application (see, for example, FIGS. 20A-20B or FIGS. 22A-22B), the structure can further include a semiconductor buffer layer 34 located between the first source/drain region and the backside source/drain contact placeholder structure 32.

In embodiments of the present application (see, for example, FIGS. 20A-20B or FIGS. 22A-22B), the structure can further include a frontside BEOL structure 44 electrically connected to the first source/drain region by a frontside source/drain contact structure 42A.

In embodiments of the present application, the structure can further include a semiconductor buffer layer located between the second source/drain region and the backside source/drain contact structure 52.

In embodiments of the present application, each semiconductor channel material nanosheet 18NS of the plurality of spaced apart and vertically stacked semiconductor channel material nanosheets is dumb-bell shaped having a middle portion having a first thickness and two end portions having a second thickness that is greater than the first thickness.

In embodiments of the present application, the backside source/drain contact structure 52 has a first portion and a second portion, wherein the second portion of the backside source/drain contact structure is closest to the second source/drain region than the first portion, and wherein an uppermost segment of the second portion is confined by a protective liner 30L.

In embodiments of the present application, the first portion has a first critical dimension CD1, and the second portion has a second critical dimension CD2, wherein CD2 is less than CD1.

In embodiments of the present application, the first portion of the backside source/drain contact structure 52 contacts a backside interconnect structure 54.

In another embodiment of the present application (see, for example, FIGS. 20A-20B or FIGS. 22A-22B), the semiconductor structure includes a nanosheet transistor including a plurality of spaced apart and vertically stacked semiconductor channel material nanosheets (i.e., stack of semiconductor channel material nanosheets 18NS illustrated in FIGS. 20A-20B and 22A-22B), a gate structure 40 wrapped around the plurality of spaced apart and vertically stacked semiconductor channel material nanosheets, a first source/drain region (i.e., source/drain region 36 on the left-hand side of FIGS. 20A and 22A) located on a first side of the gate structure 40 and a second source/drain region (i.e., source/drain region 36 on the left-hand side of FIGS. 20A and 22A) located on a second side of the gate structure 40, wherein the gate structure 40 has a first gate thickness TG1 under a bottommost semiconductor channel material nanosheet of the plurality of spaced apart and vertically stacked semiconductor channel material nanosheets that is greater than a second gate thickness TG2 that is located between the bottommost semiconductor channel material nanosheet and a nearest overlying semiconductor channel material nanosheet of the plurality of spaced apart and vertically stacked semiconductor channel material nanosheets. The structure of this embodiment further includes a bottom inner spacer structure 28S located laterally adjacent to the first gate thickness TG1 of the gate structure 40, an upper inner spacer (i.e., inner spacer 28 located directly above the bottom inner spacer structure 28S) located above the bottom inner spacer structure 28S and positioned laterally adjacent to the second gate thickness TG2 of the gate structure 40, a backside source/drain contact structure 52 electrically contacting the second source/drain region of the nanosheet transistor; and a backside source/drain contact placeholder structure 32 located beneath the first source/drain region, wherein a semiconductor buffer layer 34 is located between the first source/drain region and the backside source/drain contact placeholder structure 32.

In embodiments of the present application (see, for example, FIGS. 20A-20B or FIGS. 22A-22B), the bottom inner spacer structure 28S includes a first inner spacer and a second inner spacer, wherein the first inner spacer is vertically spaced apart from the second inner spacer by a semiconductor material liner 18L.

In embodiments of the present application, each semiconductor channel material nanosheet 18NS of the plurality of spaced apart and vertically stacked semiconductor channel material nanosheets and the semiconductor material liner 18L are composed of a compositionally same semiconductor material.

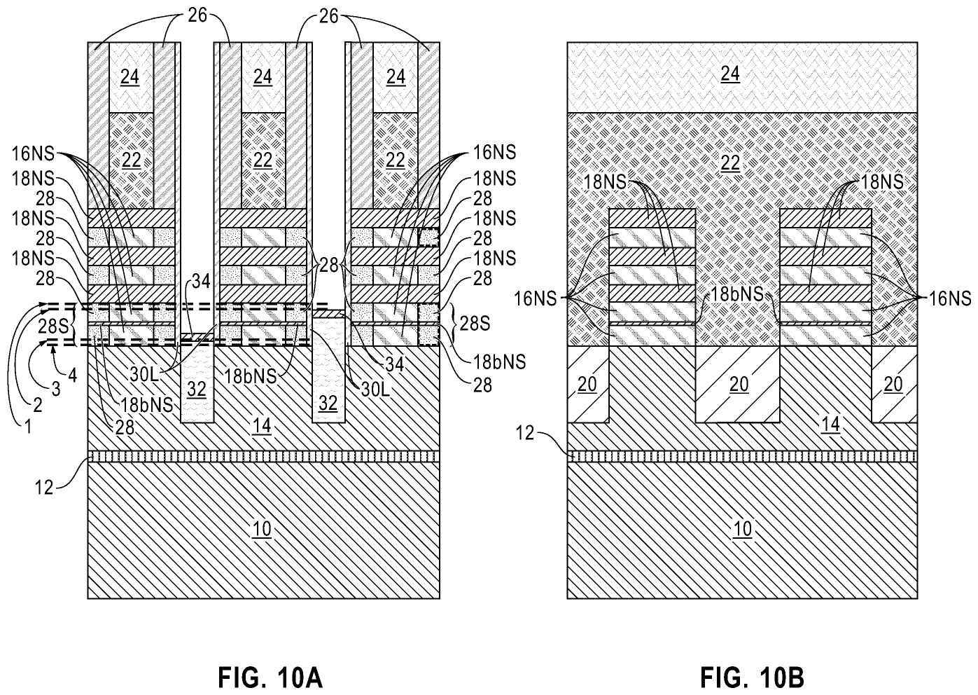

In embodiments of the present application (see, for example, FIG. 10A and FIGS. 20A-20B or FIGS. 22A-22B), a topmost surface of the bottom inner spacer structure 28S is at a first level, a topmost surface of the semiconductor buffer layer 34 is at a second level, a topmost surface of the backside source/drain contact placeholder structure 32 is located at a third level, and a bottommost surface of the bottom inner spacer structure 28S is located at a fourth level, wherein the first level is greater than the second level, and the third level is greater than the fourth level

In embodiments (see, for example, FIGS. 20A-20B or FIGS. 22A-22B), the backside source/drain contact structure 52 has a first portion and a second portion, wherein the second portion of the backside source/drain contact structure 52 is closest to the second source/drain region than the first portion, and wherein an uppermost segment of the second portion is confined by a protective liner 30L.

In embodiments of the present application, the first portion has a first critical dimension, and the second portion has a second critical dimension, wherein the second critical dimension is less than the first critical dimension.

In embodiments of the present application, the first portion of the backside source/drain contact structure 52 contacts a backside interconnect structure 54.

In embodiments, the structure further includes frontside BEOL structure 44 electrically connected to the first source/drain region by a frontside source/drain contact structure 42A.

In a further embodiment of the present application (see, for example, FIGS. 20A-20B or FIGS. 22A-22B), the semiconductor structure includes a nanosheet transistor including a plurality of spaced apart and vertically stacked semiconductor channel material nanosheets (i.e., semiconductor channel material nanosheets 18NS), a gate structure 40 wrapped around the plurality of spaced apart and vertically stacked semiconductor channel material nanosheets, a first source/drain region (i.e., source/drain region 36 on the left-hand side of FIGS. 20A and 22B) located on a first side of the gate structure 40 and a second source/drain region (i.e., source/drain region 36 located on the right-hand side of FIGS. 20A and 20B) located on a second side of the gate structure 40, wherein the gate structure 40 has a first gate thickness TG1 under a bottommost semiconductor channel material nanosheet of the plurality of spaced apart and vertically stacked semiconductor channel material nanosheets that is greater than a second gate thickness TG2 that is located between the bottommost semiconductor channel material nanosheet and a nearest overlying semiconductor channel material nanosheet of the plurality of spaced apart and vertically stacked semiconductor channel material nanosheets. In this embodiment, the structure further includes a bottom inner spacer structure 28S having a first vertical height and located laterally adjacent to the first gate thickness TG1 of the gate structure 40, the bottom inner spacer structure 28S including a first inner spacer and a second inner spacer that are vertically spaced apart by a semiconductor material liner 18L, and an upper inner spacer (i.e., inner spacer 28 located directly above the bottom inner spacer structure 28S) having a second vertical height and located above the bottom inner spacer structure 28S and positioned laterally adjacent to the second gate thickness TG2 of the gate structure 40, wherein the first vertical height is greater than the second vertical height.

In embodiments of the present application, the first vertical height is substantially equal to the first gate thickness and the second vertical height is substantially equal to the second gate thickness.

In embodiments of the present application, each semiconductor channel material nanosheet 18NS of the plurality of spaced apart and vertically stacked semiconductor channel material nanosheets and the semiconductor material liner are composed of a compositionally same semiconductor material.

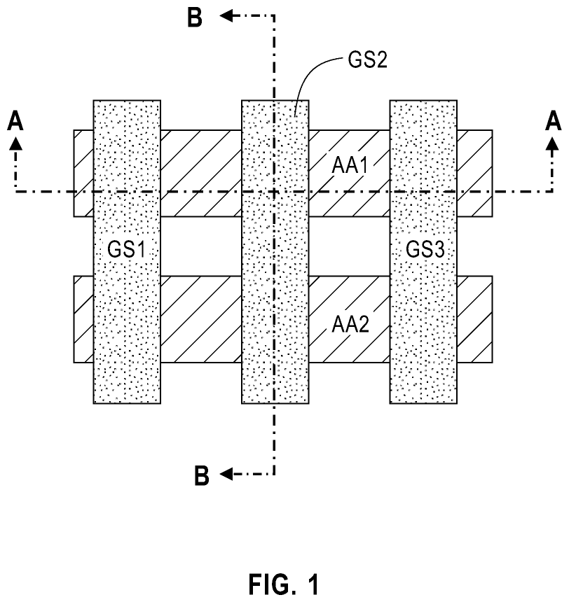

Reference is now made to FIG. 1 which illustrates an exemplary semiconductor device layout that can be employed in accordance with an embodiment of the present application. The semiconductor device layout includes a plurality of active areas, e.g., first active area AA1 and second active area AA2, oriented along a first direction, and a plurality of functional gate structures, e.g., GS1, GS2 and GS3, that are oriented in a second direction which is perpendicular to the first direction; in the drawing cut A-A and cut B-B are shown. By way of an example, three functional gate structures, GS1, GS2 and GS3, and two active areas, AA1 and AA2, are shown. Cut A-A is through a length-wise direction of AA1 and through each of GS1, GS2 and GS3, and cut B-B is through a length-wise direction of GS2, and through AA1 and AA2.

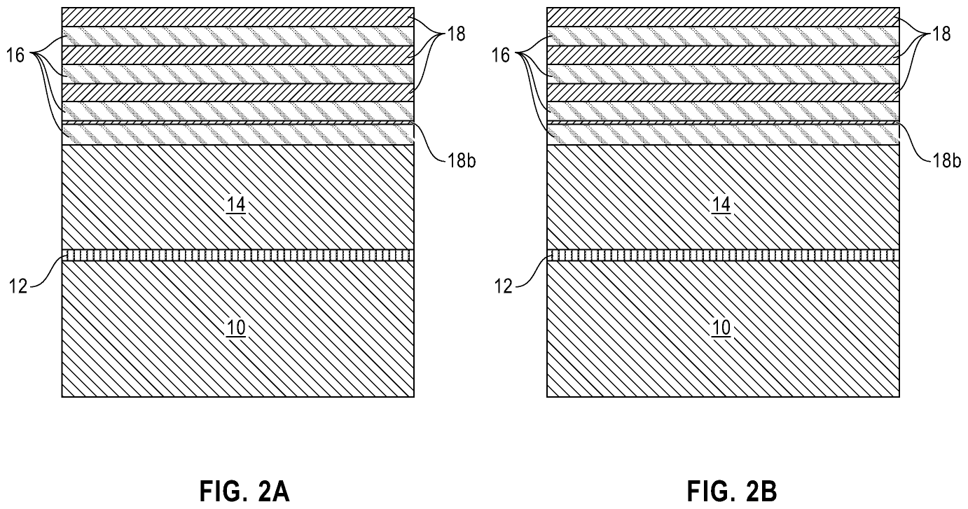

Referring now to FIGS. 2A and 2B, there is illustrated an exemplary semiconductor structure corresponding to cuts A-A and B-B shown in FIG. 1, respectively, that can be employed in the present application. The semiconductor structure includes a first semiconductor layer 10, an etch stop layer 12, a second semiconductor layer 14, and a material stack of alternating sacrificial semiconductor material layers 16 and semiconductor channel material layers 18, 18b, wherein element 18b represents a bottommost semiconductor channel material layer, and element 18 represents other semiconductor channel material layers within the material stack. In the present application, the bottommost semiconductor channel material layer 18b is intentionally designed to have a thickness that is less than the other semiconductor channel material layers 18 of the material stack. Due to placeholder position variation, the bottommost nanosheet is not suitable as a channel nanosheet because sometimes it could be attached to the S/D epi (i.e., source/drain region 36) or sometimes it is not if the backside source/drain contact placeholder structure 32 grows too high. Therefore, forming a thinner bottommost nanosheet is easier to be removed later as a sacrificial nanosheet.

In the present application, the first semiconductor layer 10, the etch stop layer 12 and the second semiconductor layer 14 can be components of a substrate. The first semiconductor layer 10 is composed of a first semiconductor material, and the second semiconductor layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the second semiconductor layer 14 can be compositionally the same as, or compositionally different from, the first semiconductor material that provides the first semiconductor layer 10.

In some embodiments of the present application, the etch stop layer 12 can be composed of a dielectric material such as, for example, silicon dioxide and/or boron nitride. In other embodiments of the present application, the etch stop layer 12 is composed of a semiconductor material that is compositionally different from the first semiconductor material that provides the first semiconductor layer 10 and the second semiconductor material that provides the second semiconductor layer 14. In one example, the first semiconductor layer 10 is composed of silicon, the etch stop layer 12 is composed of silicon dioxide, and the second semiconductor layer 14 is composed of silicon. In another example, the first semiconductor layer 10 is composed of silicon, the etch stop layer 12 is composed of silicon germanium, and the second semiconductor layer 14 is composed of silicon.

The substrate including the first semiconductor layer 10, the etch stop layer 12 and the second semiconductor layer 14 can be formed utilizing techniques well known to those skilled in the art. For example, the substrate including the first semiconductor layer 10, the etch stop layer 12 and the second semiconductor layer 14 can be formed by a separation by ion implantation of oxygen process, or wafer bonding. Alternatively, the substrate including the first semiconductor layer 10, the etch stop layer 12 and the second semiconductor layer 14 can be formed by deposition of the various substrate layers one on top the other. The deposition used in forming the various substrate layers can include, but is not limited to, chemical vapor deposition (CVD), plasma enhanced chemical vapor deposition (PECVD), or epitaxial growth. The terms “epitaxial growth” or “epitaxially growing” means the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking.

As mentioned above, the material stack includes alternating sacrificial semiconductor material layers 16 and semiconductor channel material layers 18, 18b. In some embodiments and as is illustrated in FIGS. 2A and 2B, there is an equal number of sacrificial semiconductor material layers 16 and semiconductor channel material layers 18, 18b. That is, the material stack can include ‘n’ number of semiconductor channel material layers 18, 18b and ‘n’ number of sacrificial semiconductor material layers 16, wherein n is an integer greater than one. By way of one example, the material stack includes four sacrificial semiconductor material layers 16 and four semiconductor channel material layers 18, 18b. Each sacrificial semiconductor material layer 16 is composed of a third semiconductor material, while each semiconductor channel material layer 18, 18b is composed of a fourth semiconductor material that is compositionally different from the third semiconductor material. In some embodiments, the fourth semiconductor material that provides each semiconductor channel material layer 18, 18b can provide high channel mobility for n-type field effect transistor (FET) devices. In other embodiments, the fourth semiconductor material that provides each semiconductor channel material layer 18, 18b can provide high channel mobility for p-type FET devices. The third semiconductor material that provides each sacrificial semiconductor material layer 16, and the fourth semiconductor material that provides each semiconductor channel material layer 18, 18b can include one of the semiconductor materials mentioned above. In one example, the third semiconductor material that provides each sacrificial semiconductor material layer 16 is composed of a silicon germanium alloy having a germanium content from 20 atomic percent to 40 atomic percent and the fourth semiconductor material that provides each semiconductor channel material layer 18, 18b is composed of silicon. Other combinations of semiconductor materials are possible as long as the third semiconductor material that provides each sacrificial semiconductor material layer 16 is compositionally different from the fourth semiconductor material that provides each semiconductor channel material layer 18, 18b.

The material stack including the alternating sacrificial semiconductor material layers 16 and semiconductor channel material layers 18, 18b can be formed by CVD, PECVD, epitaxial growth or any combination of such deposition processes.

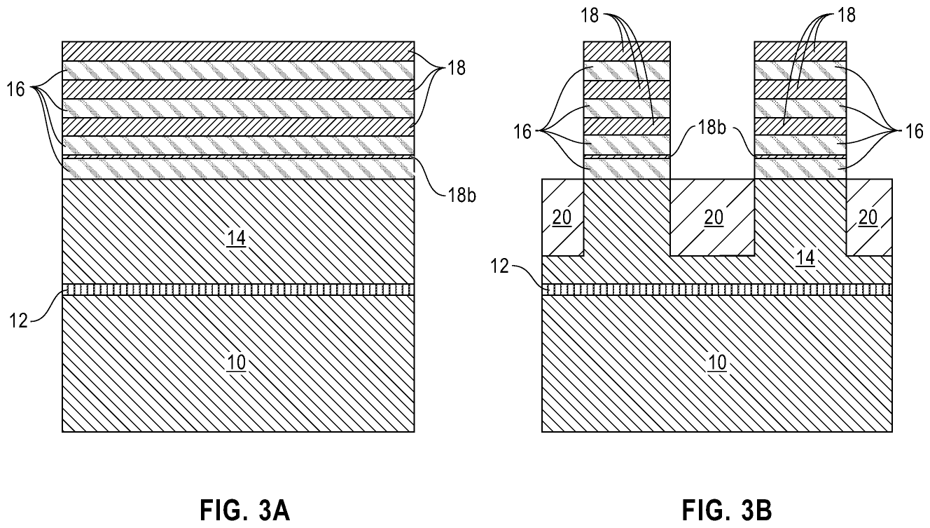

Referring now to FIGS. 3A and 3B, there are illustrated the exemplary semiconductor structure shown in FIGS. 2A and 2B, respectively, after patterning the material stack, and forming a shallow trench isolation structure 20. The patterning of the material stack includes lithography and etching. Lithography includes forming a photoresist material on a layer or a stack of layers that need to be patterned, exposing the photoresist material to a pattern of irradiation, and developing the exposed photoresist material. The etch can include reactive ion etching (RIE), ion beam etching (IBE), plasma etching or any combination thereof. This etch etches through an entirety of the material stack and stops on a surface of the second semiconductor layer 14. After etching the remaining photoresist material can be removed utilizing a conventional photoresist removal process.

After this patterning process, at least one patterned material stack is formed. In the illustrated example, and as shown in FIG. 2B, two patterned material stacks are formed. Each patterned material structure includes a remaining (i.e., non-etched) portion of each sacrificial semiconductor layer 16 and a remaining (i.e., non-etched) portion of each semiconductor channel material layer 18, 18b. In the present application, each remaining (i.e., non-etched) portion of sacrificial semiconductor layers 16 in the patterned material stack can be referred to a patterned sacrificial semiconductor layer, while each remaining (i.e., non-etched) portion of semiconductor channel material layer 18, 18b in the patterned material stack can be referred to a patterned semiconductor channel material layer.

Shallow trench isolation structure 20 is composed of any trench dielectric material such as, for example, silicon oxide. In some embodiments, a trench dielectric liner composed of, for example, SiN, can be present along a sidewall and a bottom wall of the trench dielectric material. The shallow trench isolation structure 20 has a topmost surface that is coplanar with, or slightly below, a topmost surface of the second semiconductor layer 14. The shallow trench isolation structure 20 can be formed by forming a trench in the second semiconductor layer 14, depositing the optional trench dielectric liner material and the trench dielectric material in the trench, and thereafter performing an etch back process. The shallow trench isolation structure 20 is formed on a sub-surface of the second semiconductor layer 14 and along a sidewall of a non-etched portion of the second semiconductor layer 14.

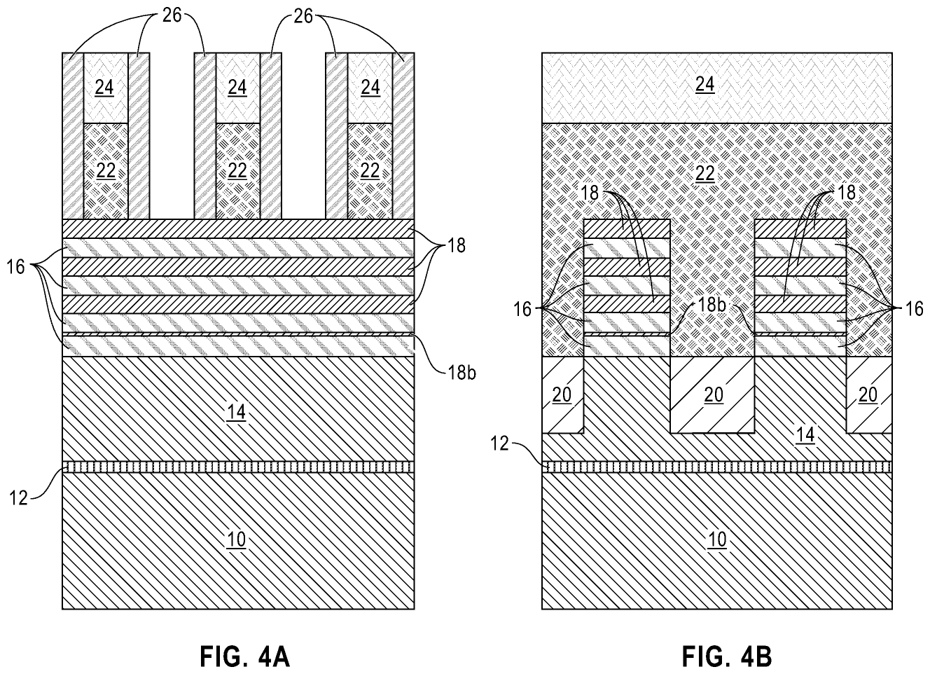

Referring now to FIGS. 4A and 4B, there are illustrated the exemplary semiconductor structure shown in FIGS. 3A and 3B, respectively, after forming a sacrificial gate structure 22, a hard mask cap 24 and a gate spacer 26. In some embodiments, the hard mask cap 24 can be omitted from the structure. In the illustrated embodiment, three sacrificial gate structures 22 are shown in FIG. 4A and each sacrificial gate structure 22 straddles over at least one of the patterned material stacks. The term “straddle” denotes that one material layer is located on a topmost surface and opposing sidewall surfaces of another material layer; the straddling aspect is shown in FIG. 4B in which the sacrificial gate structure 22 is located on top, and along sidewalls, of each patterned material stack.

The sacrificial gate structure 22 includes at least a sacrificial gate material. In some embodiments, the sacrificial gate structure 22 can also include a sacrificial gate dielectric material. In such embodiments, the sacrificial gate dielectric material would be located beneath the sacrificial gate material. The optional sacrificial gate dielectric material can be composed of a dielectric material such as, for example, silicon dioxide. The sacrificial gate material can be composed of, for example, polysilicon, amorphous silicon, amorphous silicon germanium or amorphous germanium. The hard mask cap 24 is composed of a hard mask material such as, for example, silicon nitride.

The sacrificial gate structure 22 and if present, the hard mask cap 24 can be formed by depositing the optional sacrificial gate dielectric material, depositing the sacrificial gate material and, depositing, if the hard mask cap 24 is present, the hard mask material and thereafter subjecting the as-deposited material layers to a patterning process. Patterning includes lithography and etching as defined above

The gate spacer 26, which is present along opposing sidewalls of the sacrificial gate structure 22 and, if present, the hard mask cap 24, can be composed of a dielectric spacer material including, but not limited to, silicon dioxide, SiN, SiBCN, SiOCN or SiOC. The gate spacer 28 can be formed by deposition of the dielectric spacer material, followed by a spacer etch.

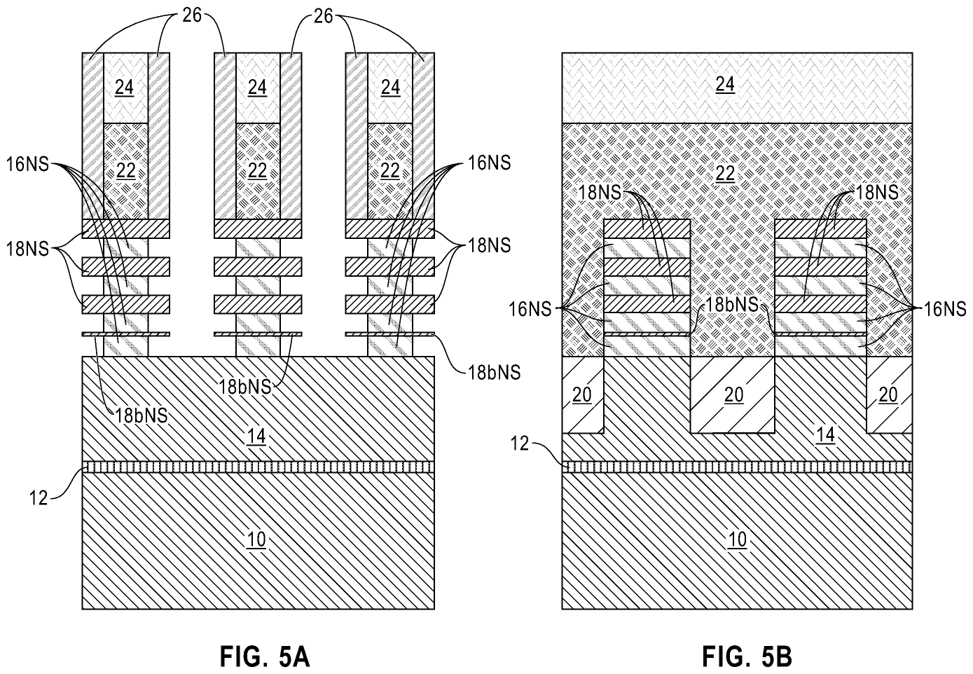

Referring now to FIGS. 5A and 5B, there are illustrated the exemplary semiconductor structure shown in FIGS. 4A and 4B, respectively, after nanosheet patterning of the previously patterned material stack, wherein the nanosheet patterning of the previously patterned material stack forms at least one nanosheet stack of alternating sacrificial semiconductor material nanosheets 16NS and semiconductor channel material nanosheets 18NS, 18bNS, and recessing, i.e., indenting, each sacrificial semiconductor material nanosheet 16NS of the at least one nanosheet stack. In the present application, semiconductor channel material nanosheet 18bNS represents a bottommost semiconductor channel material nanosheet of the nanosheet stack. This bottommost semiconductor channel material nanosheet 18bNS has a thickness that is less than the thickness of the other semiconductor channel material nanosheet 18NS of the nanosheet stack.

Nanosheet patterning utilizes the sacrificial gate structure 22, if present, the hard mask cap 24, and the gate spacer 26 that is present along at least the sidewalls of at least the sacrificial gate structure 22 as a combined etch mask. An etch such as, for example, RIE, is then employed to remove portions of the patterned material stack that are not protected by the combined etch mask. Immediately after nanosheet patterning, and prior to the recessing, the sacrificial semiconductor material nanosheets 16NS, and the semiconductor channel material nanosheets 18NS, 18bNS have a same width.

The recessing, i.e., indenting, of the sacrificial semiconductor material nanosheets 16NS includes a lateral etching process that removes end portions of each sacrificial semiconductor material nanosheet 16NS. This lateral etch does not indent the semiconductor channel material nanosheets 18NS, 18bNS.

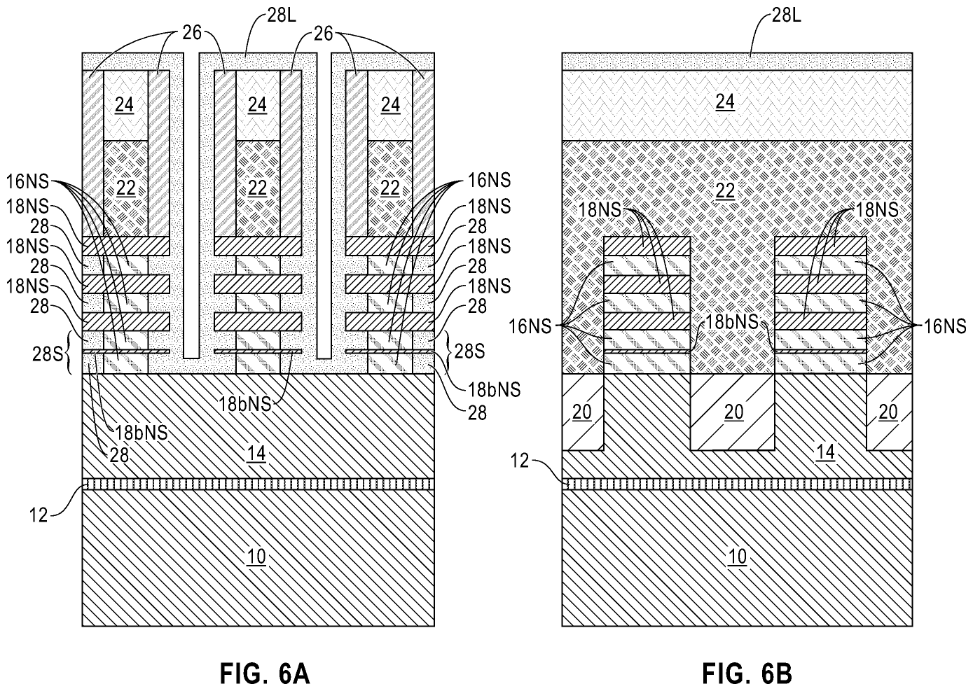

Referring now to FIGS. 6A and 6B, there are illustrated the exemplary semiconductor structure shown in FIGS. 5A and 5B, respectively, after forming a conformal inner dielectric spacer layer 28L. The term “conformal” is used throughout the present application to denote a material layer whose thickness along a horizontal surface of another material layer or structure that is the same as its thickness along a vertical surface of another material layer or structure. The conformal inner dielectric spacer layer 28L is composed of a dielectric spacer material such as, for example, silicon dioxide, SiN, SiBCN, SiOCN or SiOC. The dielectric spacer material that provides the conformal inner dielectric spacer layer 28L can be compositionally the same as, or compositionally different from, the dielectric spacer material that provides the gate spacer 26.

The conformal inner dielectric spacer layer 28L is formed utilizing any conformal deposition process such as, for example, CVD, PECVD, or atomic layer deposition (ALD). The conformal inner dielectric spacer layer 28L does not pinch-off the gate-to-gate spacer, and the conformal inner dielectric spacer layer 28L has a sufficient thickness to fill in each of the indentations (gaps) formed by the above recessing, i.e., indenting, of the sacrificial semiconductor material nanosheets 16NS.

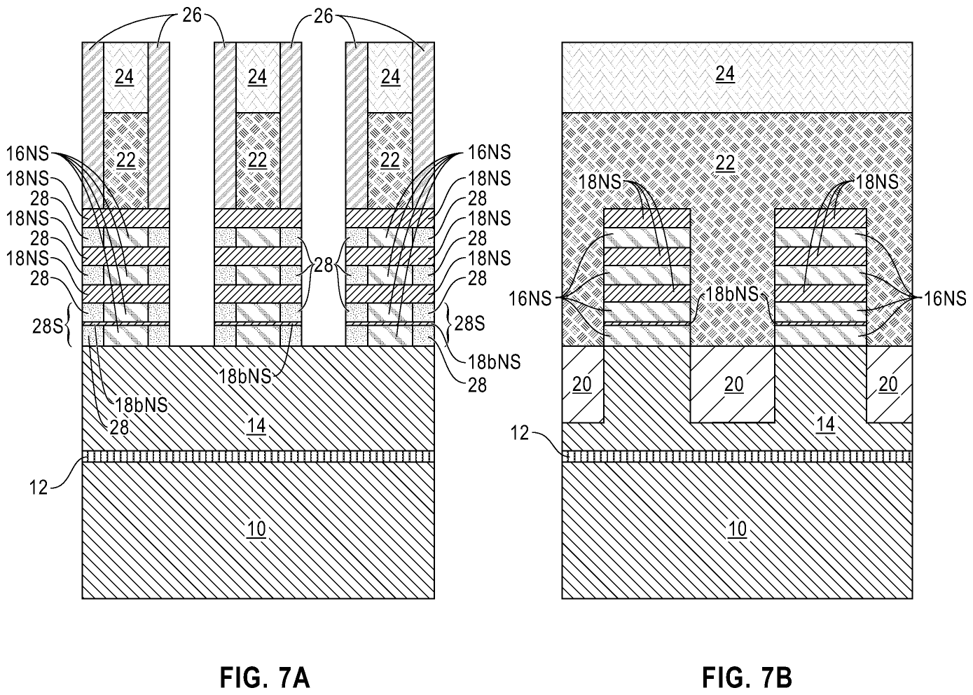

Referring now to FIGS. 7A and 7B, there are illustrated the exemplary semiconductor structure shown in FIGS. 6A and 6B, respectively, after performing an isotropic etch back process on the conformal inner dielectric spacer layer 28L to form inner spacers 28. The inner spacers 28 are located laterally adjacent to each of the recessed sacrificial semiconductor material nanosheets 16NS and each of the inner spacers 28 has an outermost edge that is vertically aligned with an outermost edge (i.e., sidewall) of the semiconductor channel material nanosheets 18NS, 18bNS.

Due to intentionally designing the bottommost semiconductor channel material layer 18b to have a thickness that is less than the other semiconductor channel material layers 18, a bottom inner spacer structure 28S such as illustrated in FIG. 7A is formed. The bottom inner spacer structure 25S includes two of the inner spacers 28 (i.e., a bottommost inner spacer and the inner spacer that is located immediately above the bottommost inner spacer) that are separated by a thin layer of semiconductor channel material (i.e., semiconductor liner 18L described hereinbelow). The remaining inner spacers 28 that are not part of the bottom inner spacer structure 28S can be referred to herein as upper inner spacers.

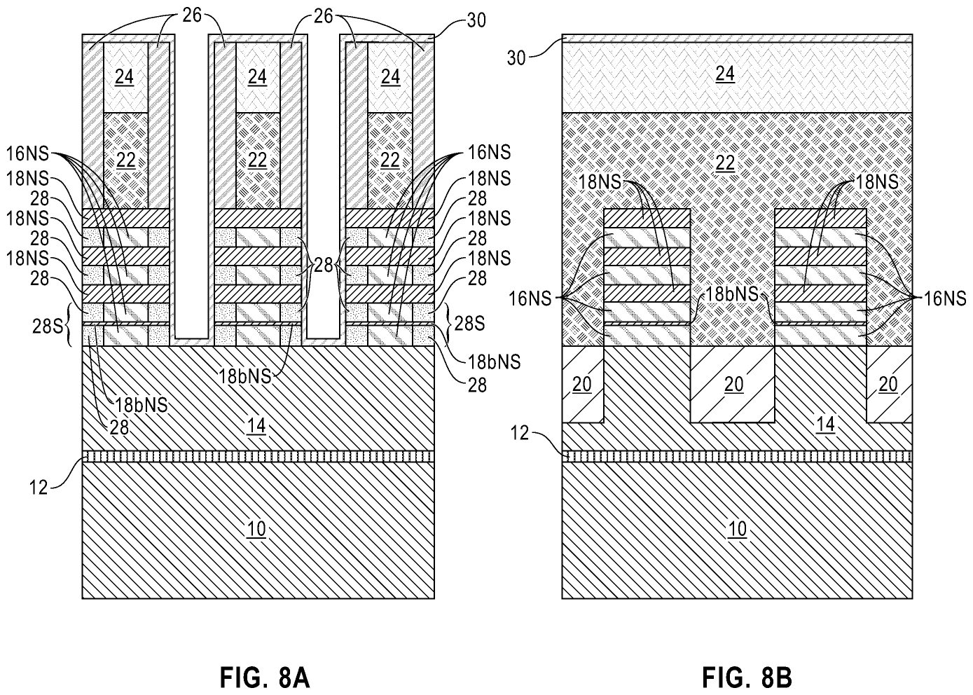

Referring now to FIGS. 8A and 8B, there are illustrated the exemplary semiconductor structure shown in FIGS. 7A and 7B, respectively, after forming a protective layer 30. The protective layer 30 is subsequently processed into a protective liner 30L, and the protective liner 30L is employed in the present application as a structure for protecting the subsequently grown source/drain regions 36 during the subsequent forming of a backside source/drain contact. The protective layer 30 is formed on all physically exposed surfaces of the exemplary structure shown in FIGS. 7A and 7B. The protective layer 30 is composed of a dielectric material that is compositionally different from the hard mask cap 24, the gate spacer 26 and the inner spacers 28. The dielectric material that provides the protective liner layer 30 can be composed of, for example, AlOₓ and TiOₓ. The protective layer 30 can be formed by deposition (e.g., CVD, PECVD or ALD). The protective layer 30 is typically a conformal layer as defined above.

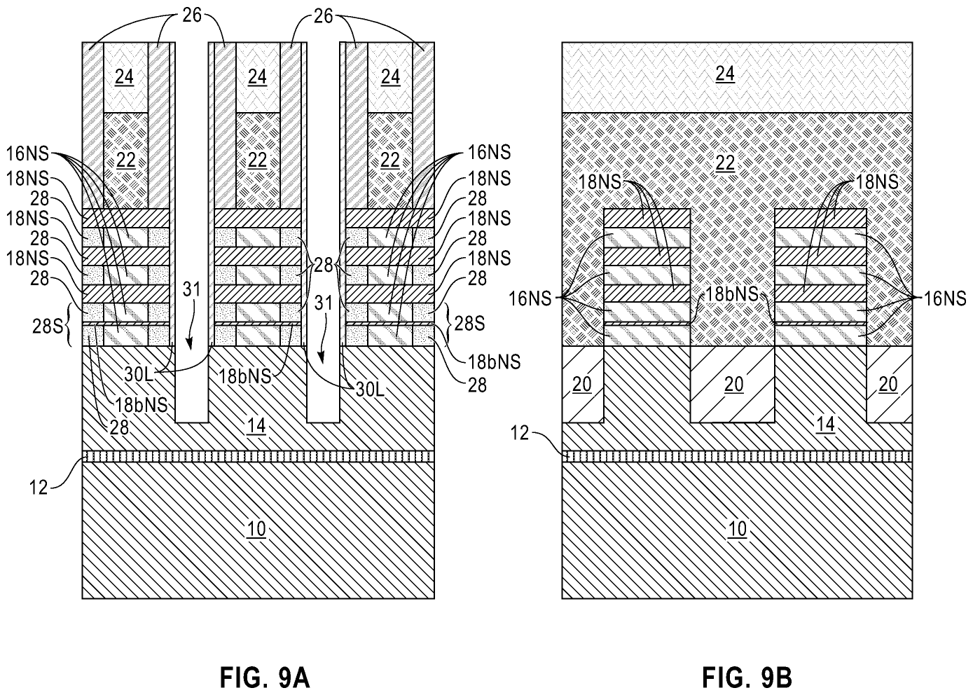

Referring now to FIGS. 9A and 9B are cross sectional views of the exemplary semiconductor structure shown in FIGS. 8A and 8B, respectively, after removing the protective layer 30 from all horizontal surfaces of the structure to provide a protective liner 30L, and forming a placeholder cavity 31 in the second semiconductor layer 14. The removal of the protective layer 30 from all horizontal surfaces of the structure includes a directional etching process and this step openings the protective layer 30. The non-etched portion of the protective layer 30 provides the protective liner 30L. The protective liner 30L is formed along a sidewall of the gate spacer 26, a sidewall of the inner spacer 28 (including the bottom inner spacer structure 28S) and along the sidewall of each semiconductor channel material nanosheet 18NS, 18bNS as is illustrated in FIG. 9A. The forming of the placeholder cavity 31 in the second semiconductor layer 14 includes a recess etch that is selective in removing the second semiconductor material that provides the second semiconductor layer 14. In one example, the recess etch includes RIE. The recess etch physically exposes a sub-surface of the second semiconductor layer 14. The term “sub-surface” as used throughout the present application denotes a surface of a material layer/structure that is located between a topmost surface and a bottommost surface of the material layer/structure.

Referring now to FIGS. 10A and 10B, there are illustrated the exemplary semiconductor structure shown in FIGS. 9A and 9B, respectively, after forming a backside source/drain contact placeholder structure 32 in the placeholder cavity and a semiconductor buffer layer 34 on the source/drain contact placeholder structure 32. Due to processing variations, different height backside source/drain contact placeholder structures 32 as shown in FIG. 10A typically form.

The backside source/drain contact placeholder structures 32 are composed of a fifth semiconductor material which is compositionally different from the second semiconductor material that provides the second semiconductor layer 14 and a sixth semiconductor material that provides the semiconductor buffer layer 34. In one example, the backside source/drain contact placeholder structures 32 are composed of a silicon germanium alloy, while the semiconductor buffer layer 34 is composed of silicon. The backside source/drain contact placeholder structures 32 can be formed by deposition (e.g., CVD, PECVD or epitaxial growth) of the fifth semiconductor material, followed by a recess etch. The semiconductor buffer layer 34 can be formed by deposition (e.g., CVD, PECVD or epitaxial growth) of the sixth semiconductor material, followed by a recess etch. Note that a lower portion of the protective liner 30L is present along sidewalls of the semiconductor buffer layer 34 and, in some instances, an upper portion of the sidewalls of the backside source/drain contact placeholder structures 32.

In the present application, the backside source/drain contact placeholder structures 32 have a height in which the topmost surface of each backside source/drain contact placeholder structure 32 is anywhere between the topmost surface of the second semiconductor layer 14 to below a topmost surface of the bottom inner spacer structure 28S. Level 1, level 2, level 3 and level 4 are shown by means of dotted lines in FIG. 10A. Level 1 represents a first level that is at a topmost surface of the bottom inner spacer structure 28S, level 2 represents a second level that is at a topmost surface of one of the semiconductor buffer layers (i.e., the semiconductor buffer layer 34 on the right-hand side of FIG. 10A), level 3 represents a third level that is at a topmost surface of one of the backside source/drain contact placeholder structures (i.e., the backside source/drain contact placeholder structure 32 on the left-hand side of the FIG. 10A), and level 4 represents a fourth level that is at a bottommost surface of the bottom inner spacer structure 28S. In the present application, level 1 must be higher than level 2 to make sure all semiconductor channel material nanosheets 18NS are connected to S/D epi, i.e., source/drain region 36, and level 3 must be higher than level 4. In the present application, and due to formation of the bottom inner spacer structure 28S (which is about 2 times thicker than the other (i.e., upper) inner spacers 28 not present in the bottom inner spacer structure 28S), the process window for placeholder margin is adequate considering 3 sigma process variations including placeholder cavity 31, etching, and backside source/drain contact placeholder structures 32 formation.

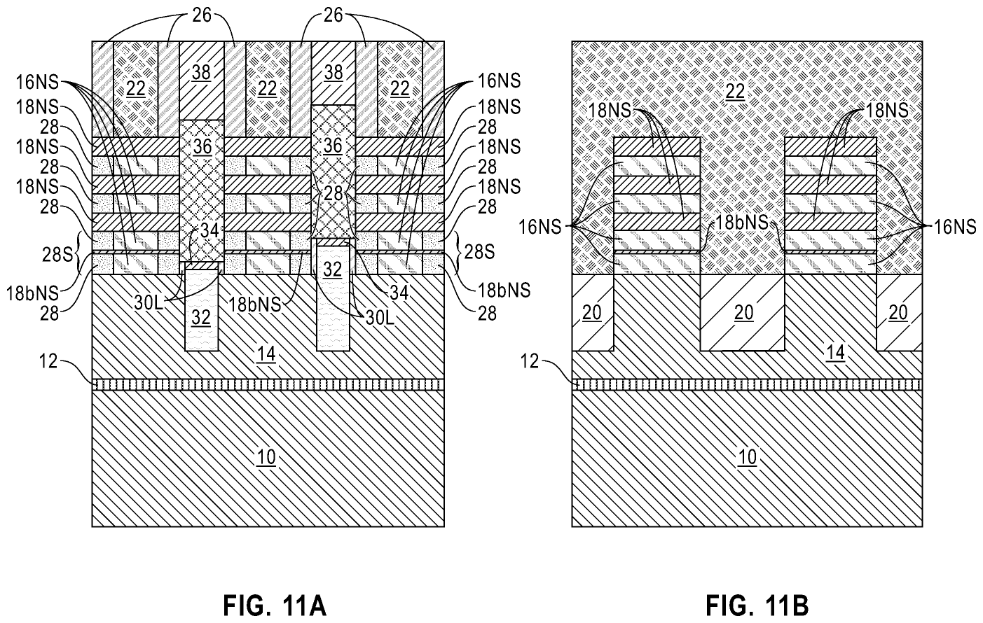

Referring now to FIGS. 11A and 11B, there are illustrated the exemplary semiconductor structure shown in FIGS. 10A and 10B, respectively, after removing an upper portion of the protective liner 30L and forming source/drain regions 36 on the semiconductor buffer layer 34, and forming a first frontside interlayer dielectric (ILD) layer 38 on the source/drain regions 36.

The upper portion of the protective liner 30L is removed utilizing an etch that is selective in removing the dielectric material that provides the protective layer 30. A lower portion of the protective liner 30L that is present along sidewalls of the semiconductor buffer layer 34 and, in some instances, an upper portion of the sidewalls of the backside source/drain contact placeholder structures 32 remains as is shown in FIG. 11A. In the present application, each nanosheet transistor that is formed will include a pair of source/drain regions 36. Due to the process variations, one of the source/drain regions (i.e., a first source/drain region) of the pair of source/drain regions 36 can have a vertical height that differs from a vertical height of the other source/drain region (i.e., a second source/drain region of the pair of source/drain regions 36, See, for example, FIG. 10A).

The source/drain regions 36 are typically formed by an epitaxial growth process, as defined above. A recess etch can follow the epitaxial growth process. The source/drain regions 36 extend outward from a physically exposed sidewall of each semiconductor channel material nanosheet 18NS and upward from the semiconductor buffer layer 34; when the bottommost semiconductor channel material nanosheet 18bNS is physically exposed, the source/drain regions 36 can be grown outward from the physically exposed sidewalls of the bottommost semiconductor channel material nanosheet 18bNS. Each of the source/drain regions 36 is composed of a seventh semiconductor material and a dopant. As used herein, a “source/drain” region can be a source region or a drain region depending on subsequent wiring and application of voltages during operation of the transistor. The seventh semiconductor material that provides the source/drain regions 36 can be compositionally the same, or compositionally different from, the fourth semiconductor material that provides each semiconductor channel material nanosheet 18NS, 18bNS. The dopant that is present in the source/drain regions 36 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each source/drain region 36 can have a dopant concentration of from 4×10²⁰ atoms/cm³ to 3×10²¹ atoms/cm³.

Next, first frontside ILD layer 38 is formed on top of and laterally adjacent to each source/drain region 36. The first frontside ILD layer 38 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer, or any combination thereof. The term “low-k” as used throughout the present application denotes a dielectric material that has a dielectric constant of less than 4.0 (all dielectric constants mentioned herein are relative to a vacuum unless otherwise noted). The first frontside ILD layer 38 can be formed by a deposition process including, but not limited to, CVD, PECVD or spin-on coating. A planarization process such as, for example, chemical mechanical polishing (CMP) follows the deposition process. The planarization process can remove an upper portion of the gate spacer 26, and if present, the hard mask cap 24. This planarization process reveals the sacrificial gate structure 22 as is illustrated in FIGS. 11A and 11B.

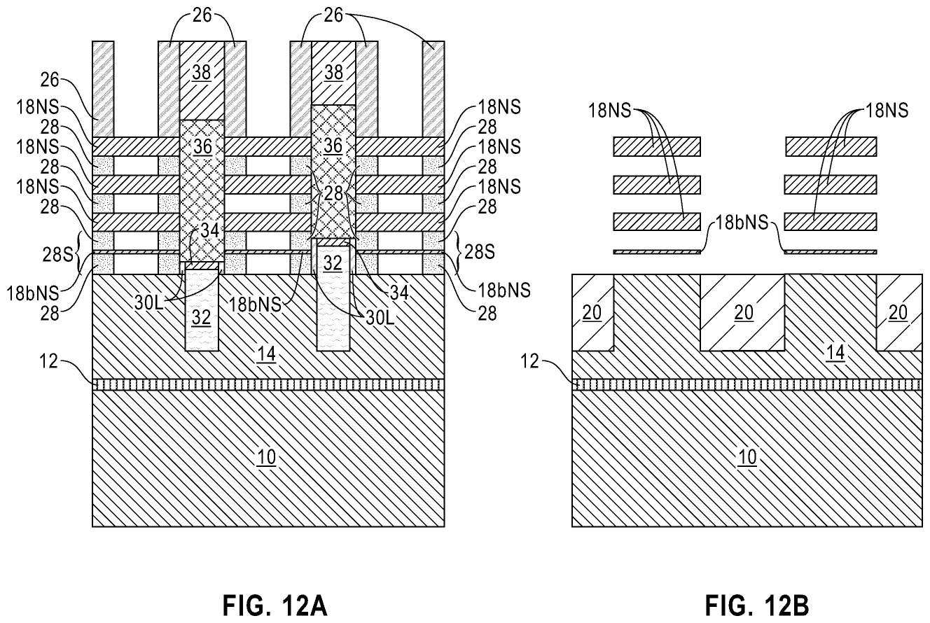

Referring now to FIGS. 12A and 12B, there are illustrated the exemplary semiconductor structure shown in FIGS. 11A and 11B, respectively, after removing the sacrificial gate structure 22 to reveal an underlying nanosheet stack, and removing each sacrificial semiconductor material nanosheet 16NS of the revealed nanosheet stack. The sacrificial gate structure 22 can be removed from the structure utilizing a material removal process such as, for example, etching, that is selective in removing the sacrificial gate structure 22. This material removal steps revels the underlying nanosheet stack. After revealing the nanosheet stack, each sacrificial semiconductor material nanosheet 16NS is removed to suspend a portion of each semiconductor channel material nanosheet 18NS, 18bNS. Each sacrificial semiconductor material nanosheet 16NS is removed utilizing any material removal process such as, for example, etching, which is selective in removing the sacrificial semiconductor material nanosheets 16NS.

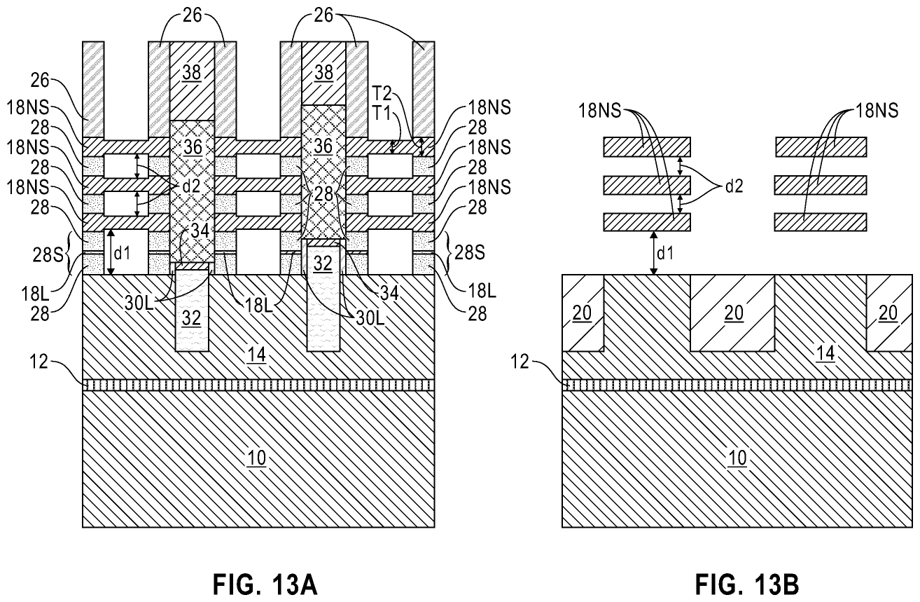

Referring now to FIGS. 13A and 13B, there are illustrated the exemplary semiconductor structure shown in FIGS. 12A and 12B, respectively, after performing a nanosheet trimming process, wherein the nanosheet trimming process removes a physically exposed portion of the bottommost semiconductor channel material nanosheet 18bNS of the nanosheet stack. The nanosheet trimming process can include oxidation, followed by an etch. A portion of the bottommost semiconductor channel material nanosheet 18bNS remains between the two inner spacers that define the bottom inner spacer structure 28S mentioned above. The remaining bottommost semiconductor channel material nanosheet 18bNS can be referred to herein as a semiconductor material liner 18L. The semiconductor material liner 18L can have a thickness from 2 nm to 6 nm. This trimming process thins the physically exposed portion of each of the remaining semiconductor channel material nanosheet 18NS providing dumb-bell shaped semiconductor channel material nanosheets having two end portions having a first thickness and a middle portion having a first thickness T1 that is located between two end portions which have a second thickness T2 that is greater than the first thickness T1. The dumb-bell shaped semiconductor channel material nanosheets are depicted in FIG. 13A. It is noted that for clarity the dumb-bell shaped semiconductor channel material nanosheets are not illustrated in the remaining drawings, but are nevertheless present in those drawings as well.

After this thinning step, a nanosheet stack is thus provided that includes spaced apart and vertically stacked semiconductor channel material nanosheets 18NS (dumb-bell shaped), in which a first distance d1, as measured from a topmost surface of the second semiconductor layer 14 to a bottommost surface of the bottommost semiconductor channel material nanosheet of the plurality of spaced apart and vertically stacked semiconductor channel material nanosheets 18NS, is greater than a second distance d2, as measured from a topmost surface of each of the semiconductor channel material nanosheets 18NS. In the present application d1 is substantially equal (within ±10%) to a vertical height of the bottom inner spacer structure 28S, and d2 is substantially equal (within ±10%) to a vertical height of the other (i.e., upper) inner spacers 28. In the present application, the vertical height of the bottom inner spacer structure 28S is greater than the vertical height of the other inner spacers 28 not present in the bottom inner spacer structure (i.e., the upper inner spacers). In subsequent processing steps of the present application, the second semiconductor layer 14 (together with the etch stop layer 12 and the first semiconductor layer 10) will be removed and backside ILD layer 48 will be formed in the area previously occupied by the second semiconductor layer 14, the etch stop layer 14 and the first semiconductor layer. When that occurs, d1 above would be measured from a topmost surface of backside ILD layer 48 to a bottommost surface of the bottommost semiconductor channel material nanosheet of the vertically separated and spaced apart semiconductor channel material nanosheets 18NS.

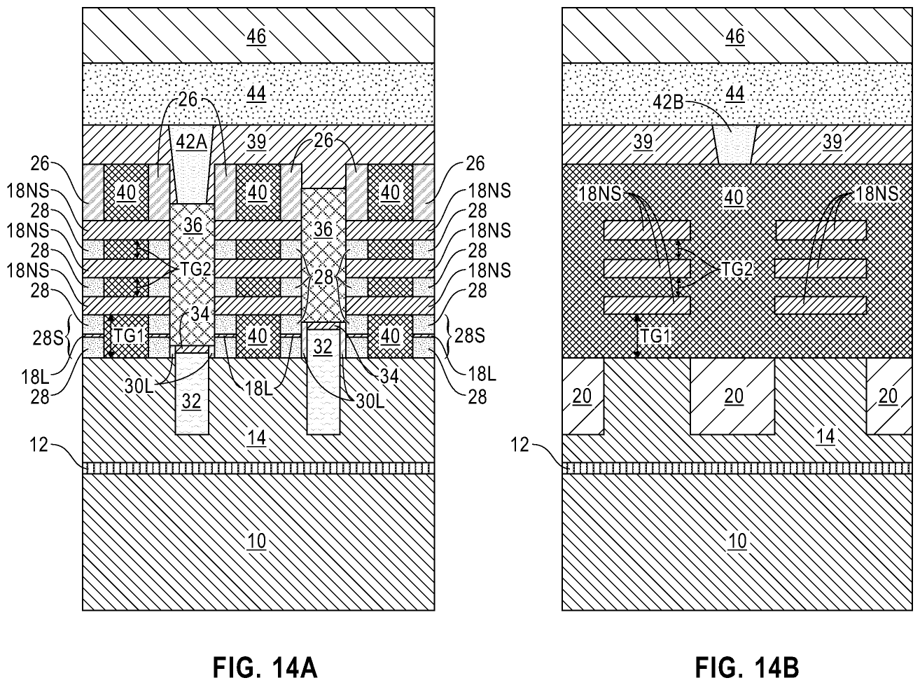

Referring now to FIGS. 14A and 14B, there are illustrated the exemplary semiconductor structure shown in FIGS. 13A and 13B, respectively, after forming a gate structure 40, and a second frontside ILD layer, wherein the first frontside ILD layer 38 and the second frontside ILD layer collectively form a middle-of-the-line (MOL) dielectric multilayered structure 39, forming frontside contact structures in the MOL dielectric multilayered structure 39, forming a frontside BEOL structure 44 and a carrier wafer 46.

The gate structure 40 is formed in the area previously accompanied by the sacrificial semiconductor material nanosheets 16NS and the bottommost semiconductor channel material nanosheet 18bNS as well as on top of the topmost semiconductor channel material nanosheet 18NS. The gate structure 40 wraps around each of the semiconductor material nanosheets 18NS within each nanosheet stack. The gate structure 40 includes a gate dielectric layer and a gate electrode; both the gate dielectric layer and the gate electrode are not separately shown in the drawing, but both are included in the area shown as the gate structure 40. As is known, the gate dielectric layer is formed directly around the suspended portion of each semiconductor channel material nanosheet 18NS and the gate electrode is formed on the gate dielectric layer. The gate dielectric layer of the gate structure 40 is composed of a gate dielectric material that has a dielectric constant of greater than 4.0. Illustrative examples of gate dielectric materials that can be used in providing the gate dielectric layer include, but are not limited to, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg).

The gate electrode of the gate structure 40 is composed of a gate electrode material. The gate electrode material can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structure 40 can be formed by deposition of the gate dielectric material and the gate electrode material, followed by a planarization process which removes any gate dielectric material and gate electrode material that is formed atop the gate spacer 26 and the first ILD layer 38.

The second frontside ILD layer includes one of the dielectric materials mentioned above for the first frontside ILD layer 38. The dielectric material that provides the second frontside ILD layer can be compositionally the same as, or compositionally different from, the dielectric material that provides the first frontside ILD layer 38. The second frontside ILD layer is formed on top of each of the gate structure 40, the gate spacer 28, and the first frontside ILD layer 38. The second frontside ILD layer can be formed utilizing one of the deposition processes mentioned above in forming the first frontside ILD layer 38. As mentioned above, the first frontside ILD layer 38 and the second frontside ILD layer collectively provide MOL dielectric multilayered structure 39 as shown in FIGS. 14A-14B.

The frontside contact structures are now formed into the MOL dielectric multilayered structure 39. The frontside contact structures include a frontside source/drain contact structure 42A and a frontside gate contact structure 42B. The frontside contact structures are formed utilizing a metallization process. The metallization process includes forming contact openings in the MOL dielectric multilayered structure 39 and then filling (including deposition and planarization) those contact openings with at least a contact conductor material. The contact conductor material that can be used for providing the frontside contact structures includes, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

In the present application, the gate structure 40 has a first thickness TG1 as measured from measured from a topmost surface of the second semiconductor layer 14 (and subsequently from the topmost surface of the backside ILD layer 48) to a bottommost surface of the bottommost semiconductor channel material nanosheet of the vertically separated and spaced apart semiconductor channel material nanosheets 18NS, and a second first thickness TG2 as measured from a topmost surface of each of the semiconductor channel material nanosheets of the plurality of spaced apart and vertically stacked semiconductor channel material nanosheets 18NS. In the present application TG1 is greater than TG2. Note TG1 is equal to d1 mentioned above, and TG2 is equal to d2 mentioned above.

Next, frontside BEOL structure 44 is formed on the uppermost surface of the MOL dielectric multilayered structure 39. The frontside BEOL structure 44 can include one or more interconnect dielectric material layers (including one of the dielectric materials mentioned above for the first frontside ILD layer 38) that contain frontside metal wires (the metal wires can be composed of any electrically conductive metal or electrically conductive metal alloy) embedded therein. Electrical contact of the frontside BEOL structure 44 to each frontside contact structure is made.

The carrier wafer 46 can include one of the semiconductor materials mentioned above for the first semiconductor layer 10. Carrier wafer 46 is bonded to the frontside BEOL structure 44 after frontside BEOL structure 44 formation. This concludes the frontside processing of the semiconductor structure.

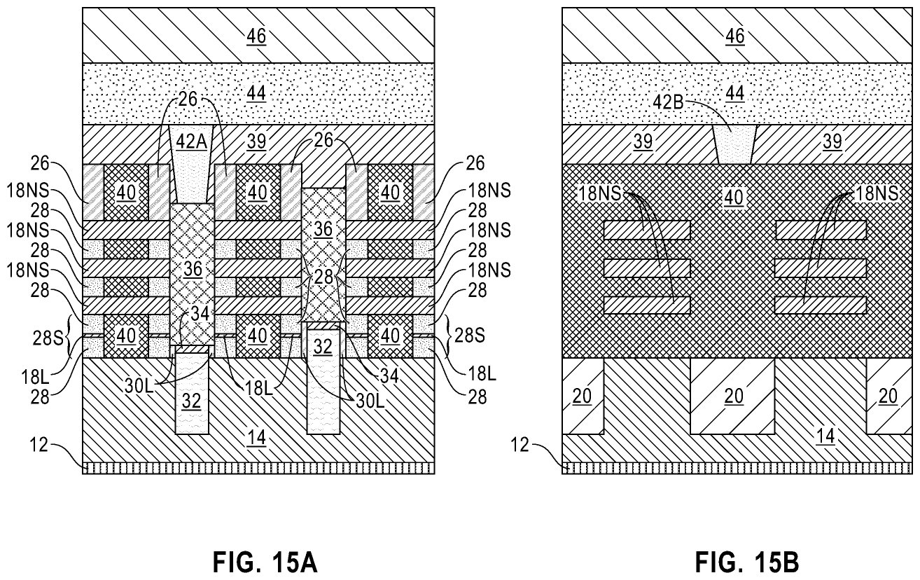

Referring now to FIGS. 15A and 15B, there are illustrated the exemplary semiconductor structure shown in FIGS. 14A and 14B, respectively, after removing the first semiconductor layer 10 to reveal the etch stop layer 12. The removal of the first semiconductor layer 10 typically includes flipping the wafer 180° to physically expose a backside of the substrate. This flipping step is not shown in the drawings of the present application for clarity. The flipping physically exposes the first semiconductor layer 10 and will allow backside processing of the exemplary structure. Flipping of the structure can be performed by hand or by utilizing a mechanical means such as, for example, a robot arm. In the illustrated embodiment, the removal of the physically exposed first semiconductor layer 10 physically exposes the etch stop layer 12. The removal of the first semiconductor layer 10 can be performed utilizing a material removal process that is selective in removing the first semiconductor material that provides the first semiconductor layer 10.

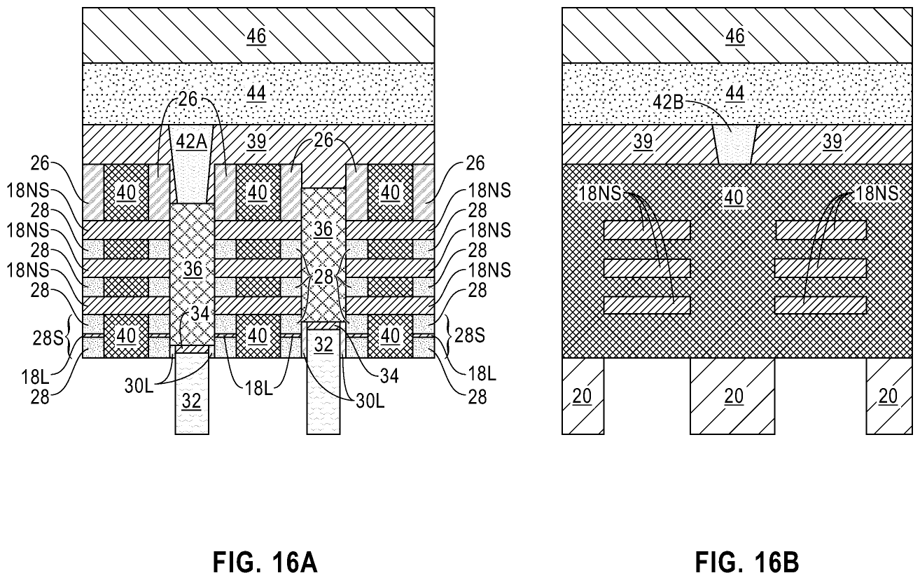

Referring now to FIGS. 16A and 16B, there are illustrated the exemplary semiconductor structure shown in FIGS. 15A and 15B, respectively, after removing the etch stop layer 12 and the second semiconductor layer 14. The removal of the etch stop layer 12 includes a material removal process that is selective in removing the etch stop layer 12. The removal of the etch stop layer 12 physically exposes the second semiconductor layer 14. The physically exposed second semiconductor layer 14 can be removed utilizing a material removal process that is selective in removing that layer from the structure. As is illustrated in FIGS. 16A-16B, the removal the etch stop layer 12 and the second semiconductor layer 14 reveals a surface of each the backside source/drain contact placeholder structure 32. Note that the removal of the second semiconductor layer 14 also reveals surfaces of the shallow trench isolation structure 22 as is illustrated in FIG. 16B.

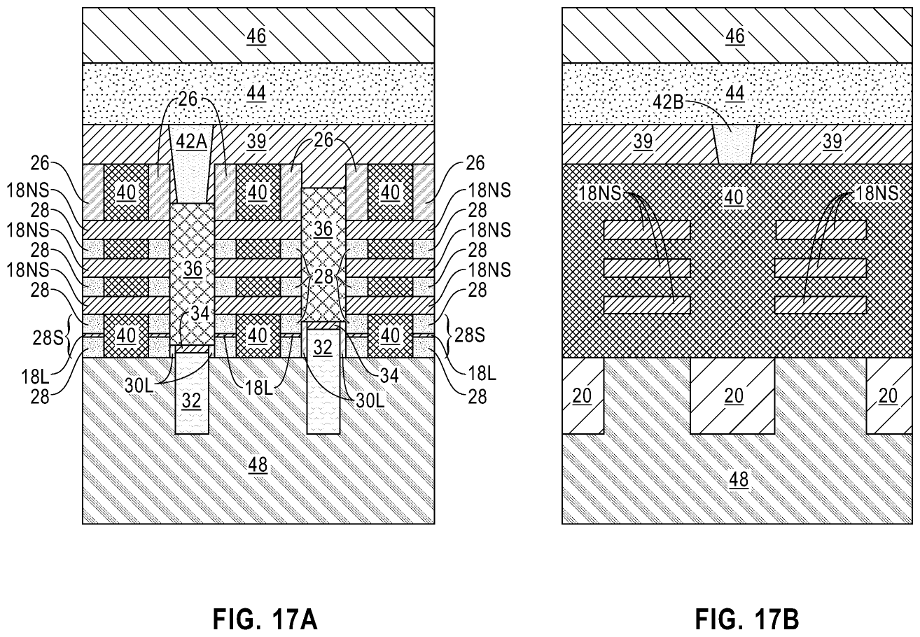

Referring now to FIGS. 17A and 17B, there are illustrated the exemplary semiconductor structure shown in FIGS. 16A and 16B, respectively, after forming a backside ILD layer 48. The backside ILD layer 50 includes one of the dielectric materials mentioned above for the first frontside ILD layer 38. The backside ILD layer 48 can be formed utilizing one of the deposition processes mentioned above in forming the first frontside ILD layer 38. The backside ILD layer 48 embeds the backside source/drain contact placeholder structure 32 and shallow trench isolation structure 20.

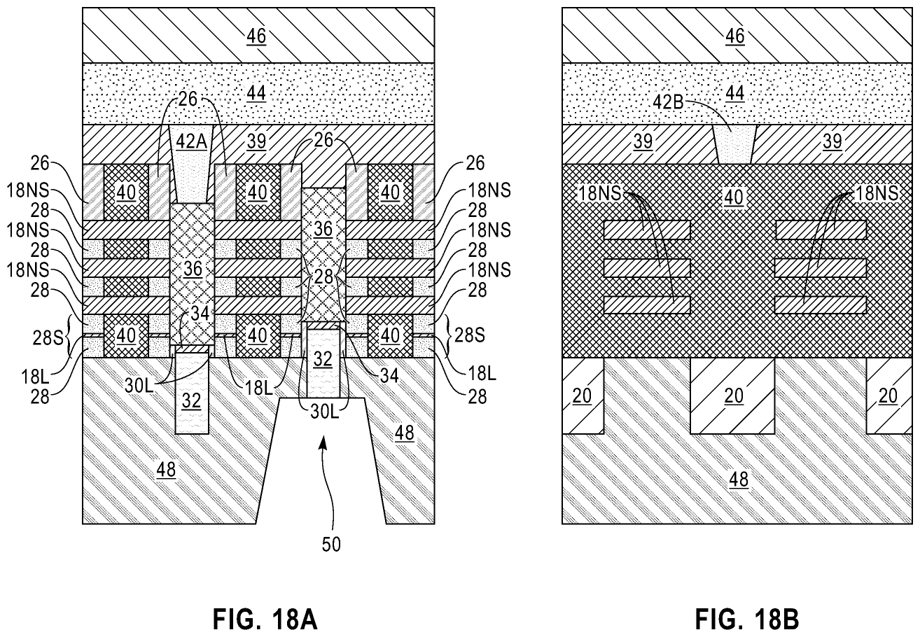

Referring now to FIGS. 18A and 18B, there are illustrated the exemplary semiconductor structure shown in FIGS. 17A and 17B, respectively, after backside contact patterning that reveals at least one of the backside source/drain contact placeholder structures 32. The backside contact patterning includes lithography and etching, wherein the etch forms an initial backside source/drain contact opening 50 in the backside ILD layer 48.

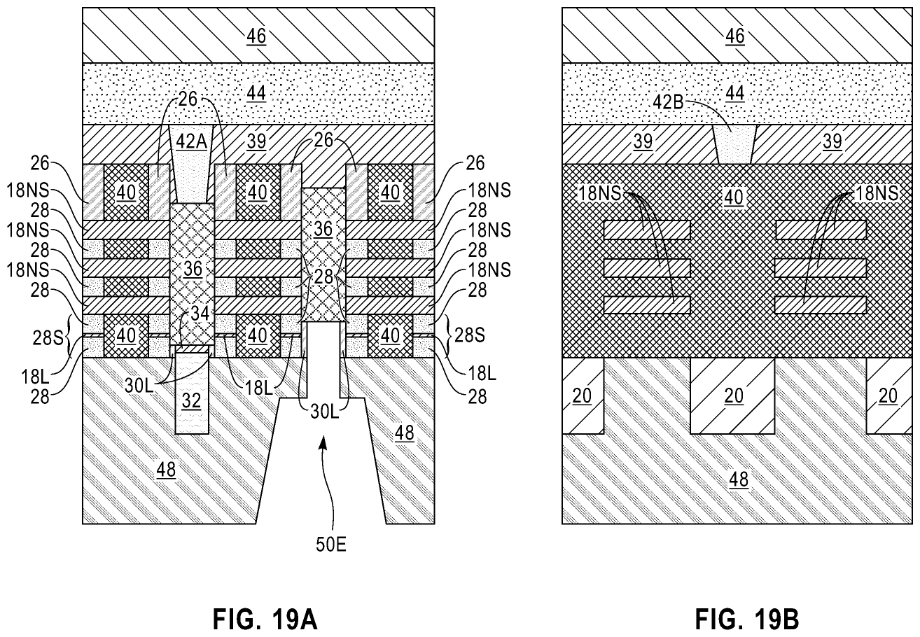

Referring now to FIGS. 19A and 19B, there are illustrated the exemplary semiconductor structure shown in FIGS. 18A and 18B, respectively, after removing the at least one revealed backside source/drain contact placeholder structure 32 and the semiconductor buffer layer 34 to physically expose one of the source/drain regions 36. In some embodiments, the physically exposed semiconductor buffer layer 34 is not removed.

The removal of the backside source/drain contact placeholder structure 32 includes a material removal process such as, for example, an etch, that is selective in removing the revealed backside source/drain contact placeholder structure 32. This removal reveals the semiconductor buffer layer 34. No damage to the source/drain regions 36 during the removal of the physically exposed occurs the backside source/drain contact placeholder structure 32. The revealed semiconductor buffer layer 34 can be removed in some embodiments utilizing a material removal process such as, for example, an etch, that is selective in removing the revealed semiconductor buffer layer 34. The removal of the semiconductor buffer layer 34 reveals one of the source/drain regions 36 as shown in FIG. 19A. These removal steps (or just the removal of the revealed backside source/drain contact placeholder structure 32) form backside source/drain contact opening 50E in the structure. As is illustrated, the backside source/drain contact opening 50E has a first portion that is self-aligned with respect to and nearest to the revealed source/drain region 36 that is narrower than a second portion of the backside source/drain contact opening 50E which is further from the revealed source/drain region 36. The backside source/drain contact opening 50E would have a similar configuration if the semiconductor buffer layer 34 is revealed.

Referring now to FIGS. 20A and 20B, there are illustrated the exemplary semiconductor structure shown in FIGS. 19A and 19B, respectively, after forming a backside source/drain contact structure 52 in direct physically contact with the physically exposed source/drain region 36 and forming a backside interconnect structure 54. In some embodiments, the backside source/drain contact structure 52 in direct physically contact with the physically exposed semiconductor buffer layer 34 that is still located on a surface of the source/drain region 36. Backside source/drain contact structure 52 includes filling (including deposition and planarization) the backside source/drain contact opening 50E with at least a contact conductor material, as defined above. Notably, the contact conductor material that can be used for providing the backside source/drain contact structure 52 includes, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above. The backside source/drain contact structure 52 that is formed includes a first portion having a first critical dimension, CD1, and a second portion having a second critical dimension, CD2, wherein CD2 is smaller than CD1. In the present application, the second portion of the backside source/drain contact structure 52 having CD2 is closest to the source/drain region 36 than the first portion of the backside source/drain contact structure 52 having CD1.

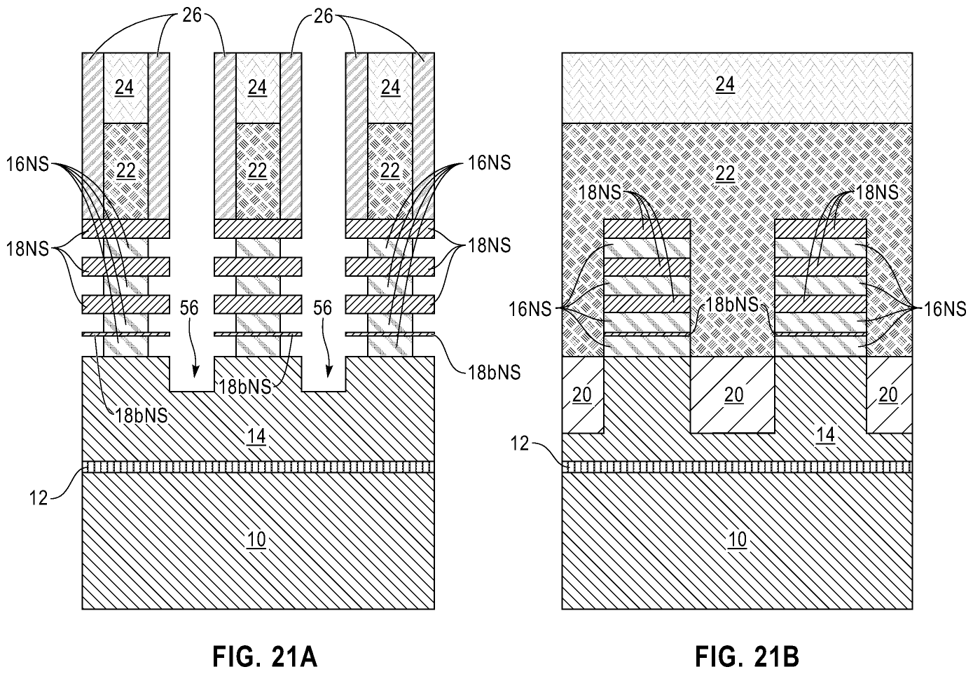

Referring now to FIGS. 21A-21B, there are illustrated the exemplary semiconductor structure shown in FIGS. 3A and 3B, respectively, after nanosheet patterning of the previously patterned material stack, wherein the nanosheet patterning of the previously patterned material stack forms at least one nanosheet stack of alternating sacrificial semiconductor material nanosheets 16NS and semiconductor channel material nanosheets 18NS, 18bNS and forms an opening (or recess) 56 in the second semiconductor layer 14, and recessing each sacrificial semiconductor material nanosheet 16NS the at least one nanosheet stack.

Nanosheet patterning utilizes the sacrificial gate structure 22, if present, the hard mask cap 24 and the gate spacer 26 that is present along at least the sidewalls of at least the sacrificial gate structure 22 as a combined etch mask. An etch such as, for example, RIE, is then employed to remove portions of the patterned material stack that are not protected by the combined etch mask. During this etch the opening 56 is formed in the second semiconductor layer 14. Immediately after nanosheet patterning, the sacrificial semiconductor material nanosheets 16NS, and the semiconductor channel material nanosheets 18NS, 18bNS have a same width.

The recessing, i.e., indenting, of the sacrificial semiconductor material nanosheets 16NS includes a lateral etching process that removes end portions of each sacrificial semiconductor material nanosheet 16NS. This lateral etch does not indent the semiconductor channel material nanosheets 18NS, 18bNS.

Referring now to FIGS. 22A-22B, there are illustrated the exemplary semiconductor structure shown in FIGS. 21A and 21B, respectively, after performing further frontside and backside processing as illustrated in FIGS. 6A and 6B to 20A and 20B.

In either the embodiment shown in FIGS. 20A-20B or the embodiment shown in FIGS. 22A-22B, a topmost surface of the bottom inner spacer structure 28S is at a first level, a topmost surface of the semiconductor buffer layer 34 is at a second level, a topmost surface of the backside source/drain contact placeholder structure 32 is located at a third level, and a bottommost surface of the bottom inner spacer structure 28S is located at a fourth level, wherein level 1 is greater than level 2 and level 3 is greater than level 4.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a nanosheet transistor comprising a plurality of spaced apart and vertically stacked semiconductor channel material nanosheets, a gate structure wrapped around the plurality of spaced apart and vertically stacked semiconductor channel material nanosheets, a first source/drain region located on a first side of the gate structure and a second source/drain region located on a second side of the gate structure, wherein the gate structure has a first gate thickness under a bottommost semiconductor channel material nanosheet of the plurality of spaced apart and vertically stacked semiconductor channel material nanosheets that is greater than a second gate thickness that is located between the bottommost semiconductor channel material nanosheet and a nearest overlying semiconductor channel material nanosheet of the plurality of spaced apart and vertically stacked semiconductor channel material nanosheets; and
a backside source/drain contact structure electrically contacting the second source/drain region of the nanosheet transistor.

2. The semiconductor structure of claim 1, further comprising a bottom inner spacer structure located laterally adjacent to the first gate thickness of the gate structure, and an upper inner spacer located above the bottom inner spacer structure and positioned laterally adjacent to the second gate thickness of the gate structure.

3. The semiconductor structure of claim 2, wherein the bottom inner spacer structure comprises a first inner spacer and a second inner spacer, wherein the first inner spacer is vertically spaced apart from the second inner spacer by a semiconductor material liner.

4. The semiconductor structure of claim 3, wherein each semiconductor channel material nanosheet of the plurality of spaced apart and vertically stacked semiconductor channel material nanosheets and the semiconductor material liner are composed of a compositionally same semiconductor material.

5. The semiconductor structure of claim 2, wherein the bottom inner spacer structure has a first vertical height, and the upper inner spacer has a second vertical height, wherein the first vertical height is greater than the second vertical height.

6. The semiconductor structure of claim 1, wherein the first source/drain region is located on a backside source/drain contact placeholder structure.

7. The semiconductor structure of claim 6, further comprising a semiconductor buffer layer located between the first source/drain region and the backside source/drain contact placeholder structure.

8. The semiconductor structure of claim 6, further comprising a frontside back-end-of-the-line (BEOL) structure electrically connected to the first source/drain region by a frontside source/drain contact structure.

9. The semiconductor structure of claim 1, further comprising a semiconductor buffer layer located between the second source/drain region and the backside source/drain contact structure.

10. The semiconductor structure of claim 1, wherein each semiconductor channel material nanosheet of the plurality of spaced apart and vertically stacked semiconductor channel material nanosheets is dumb-bell shaped having a middle portion having a first thickness and two end portions having a second thickness that is greater than the first thickness.

11. The semiconductor structure of claim 1, wherein the backside source/drain contact structure has a first portion and a second portion, wherein the second portion of the backside source/drain contact structure is closest to the second source/drain region than the first portion, and wherein an uppermost segment of the second portion is confined by a protective liner.

12. The semiconductor structure of claim 11, wherein the first portion has a first critical dimension, and the second portion has a second critical dimension, wherein the second critical dimension is less than the first critical dimension.

13. The semiconductor structure of claim 11, wherein the first portion of the backside source/drain contact structure contacts a backside interconnect structure.

14. A semiconductor structure comprising:
a nanosheet transistor comprising a plurality of spaced apart and vertically stacked semiconductor channel material nanosheets, a gate structure wrapped around the plurality of spaced apart and vertically stacked semiconductor channel material nanosheets, a first source/drain region located on a first side of the gate structure and a second source/drain region located on a second side of the gate structure, wherein the gate structure has a first gate thickness under a bottommost semiconductor channel material nanosheet of the plurality of spaced apart and vertically stacked semiconductor channel material nanosheets that is greater than a second gate thickness that is located between the bottommost semiconductor channel material nanosheet and a nearest overlying semiconductor channel material nanosheet of the plurality of spaced apart and vertically stacked semiconductor channel material nanosheets;
a bottom inner spacer structure located laterally adjacent to the first gate thickness of the gate structure;
an upper inner spacer located above the bottom inner spacer structure and positioned laterally adjacent to the second gate thickness of the gate structure;
a backside source/drain contact structure electrically contacting the second source/drain region; and
a backside source/drain contact placeholder structure located beneath the first source/drain region, wherein a semiconductor buffer layer is located between the first source/drain region and the backside source/drain contact placeholder structure.

15. The semiconductor structure of claim 14, wherein the bottom inner spacer structure comprises a first inner spacer and a second inner spacer, wherein the first inner spacer is vertically spaced apart from the second inner spacer by a semiconductor material liner.

16. The semiconductor structure of claim 15, wherein each semiconductor channel material nanosheet of the plurality of spaced apart and vertically stacked semiconductor channel material nanosheets and the semiconductor material liner are composed of a compositionally same semiconductor material.

17. The semiconductor structure of claim 14, wherein a topmost surface of the bottom inner spacer structure is at a first level, a topmost surface of the semiconductor buffer layer is at a second level, a topmost surface of the backside source/drain contact placeholder structure is located at a third level, and a bottommost surface of the bottom inner spacer structure is located at a fourth level, wherein first level is greater than the second level, and the third level is greater than fourth level.

18. The semiconductor structure of claim 14, wherein the bottom inner spacer structure has a first vertical height, and the upper inner spacer has a second vertical height, wherein the first vertical height is greater than the second vertical height.

19. The semiconductor structure of claim 14, wherein the backside source/drain contact structure has a first portion and a second portion, wherein the second portion of the backside source/drain contact structure is closest to the second source/drain region than the first portion, and wherein an uppermost segment of the second portion is confined by a protective liner.

20. The semiconductor structure of claim 19, wherein the first portion has a first critical dimension, and the second portion has a second critical dimension, wherein the second critical dimension is less than the first critical dimension.

21. The semiconductor structure of claim 19, wherein the first portion of the backside source/drain contact structure contacts a backside interconnect structure.

22. The semiconductor structure of claim 14, further comprising a frontside back-end-of-the-line (BEOL) structure electrically connected to the first source/drain region by a frontside source/drain contact structure.

23. A semiconductor structure comprising:
a nanosheet transistor comprising a plurality of spaced apart and vertically stacked semiconductor channel material nanosheets, a gate structure wrapped around the plurality of spaced apart and vertically stacked semiconductor channel material nanosheets, a first source/drain region located on a first side of the gate structure and a second source/drain region located on a second side of the gate structure, wherein the gate structure has a first gate thickness under a bottommost semiconductor channel material nanosheet of the plurality of spaced apart and vertically stacked semiconductor channel material nanosheets that is greater than a second gate thickness that is located between the bottommost semiconductor channel material nanosheet and a nearest overlying semiconductor channel material nanosheet of the plurality of spaced apart and vertically stacked semiconductor channel material nanosheets;
a bottom inner spacer structure having a first vertical height and located laterally adjacent to the first gate thickness of the gate structure, the bottom inner spacer structure comprising a first inner spacer and a second inner spacer that are vertically spaced apart by a semiconductor material liner; and
an upper inner spacer having a second vertical height and located above the bottom inner spacer structure and positioned laterally adjacent to the second gate thickness of the gate structure, wherein the first vertical height is greater than the second vertical height.

24. The semiconductor structure of claim 23, wherein the first vertical height is substantially equal to the first gate thickness and the second vertical height is substantially equal to the second gate thickness.

25. The semiconductor structure of claim 23, wherein each semiconductor channel material nanosheet of the plurality of spaced apart and vertically stacked semiconductor channel material nanosheets and the semiconductor material liner are composed of a compositionally same semiconductor material.
